(19) United States
(12) Patent Application Publication
(10) Pub. No.: US 2022/0385040 A1
(43) Pub. Date: Dec. 1, 2022

(54) VERTICAL CAVITY SURFACE EMITTING LASER

(71) Applicant: Sumitomo Electric Industries, Ltd., Osaka (JP)

(72) Inventor: Ryosuke KUBOTA, Osaka-shi (JP)

(73) Assignee: Sumitomo Electric Industries, Ltd., Osaka (JP)

(21) Appl. No.: 17/666,912

(22) Filed: Feb. 8, 2022

(30) Foreign Application Priority Data
May 26, 2021 (JP) 2021-088263

(51) Int. Cl. H01S 5/183

(52) U.S. Cl. CPC H01S 5/18338

(57) ABSTRACT

A vertical cavity surface emitting laser according to an aspect of the present disclosure includes a substrate having a main surface including a III-V group compound semiconductor and a semiconductor structure having a post disposed on the main surface. The main surface has an off-angle greater than 2° with respect to a plane. The post includes an active layer and a current confinement layer that are arranged in a first direction intersecting the main surface. The current confinement layer includes an aperture portion and an insulation portion surrounding the aperture portion. The current confinement layer has a uniaxially symmetric shape or an asymmetric shape in a section perpendicular to the first direction.

### CROSS REFERENCES TO RELATED APPLICATIONS

The present application claims priority based on Japanese Patent Application No. 2021-088263 filed in the Japan Patent Office on May 26, 2021, the entire contents of which are incorporated herein by reference.

### BACKGROUND

### 1. Field

The present disclosure relates to a vertical cavity surface emitting laser.

### 2. Related Art

Japanese Unexamined Patent Application Publication No. 2019-212669 discloses a vertical cavity surface emitting laser including a substrate having a main surface including a III-V group compound semiconductor and a semiconductor structure having a post disposed on the main surface. The post includes an active layer and a current confinement layer that are arranged in a direction perpendicular to the main surface. The vertical cavity surface emitting laser emits laser light including a plurality of modes.

### SUMMARY

The inventor has found that, when the main surface of a substrate has a small off-angle, not a lower-order mode but a higher-order mode is dominant. A lower-order mode has large optical output at the center of a cross section of laser light. A higher-order mode has large optical output at an outer portion of the cross section of laser light. When the higher-order mode is dominant, a near field pattern (NFP) tends to spread.

The present disclosure provides a vertical cavity surface emitting laser that can emit laser light having a small near field pattern.

A vertical cavity surface emitting laser according to an aspect of the present disclosure includes a substrate having a main surface including a III-V group compound semiconductor and a semiconductor structure having a post disposed on the main surface. The main surface has an off-angle greater than 2° with respect to a (100) plane. The post includes an active layer and a current confinement layer that are arranged in a first direction intersecting the main surface. The current confinement layer includes an aperture portion and an insulation portion surrounding the aperture portion. The current confinement layer has a uniaxially symmetric shape or an asymmetric shape in a section perpendicular to the first direction.

### BRIEF DESCRIPTION OF THE DRAWINGS

FIG. 1 is a schematic plan view of a vertical cavity surface emitting laser according to an embodiment.

FIG. 2 is a sectional view taken along line II-II of FIG. 1.

FIG. 3 a sectional view of a current confinement layer of a vertical cavity surface emitting laser according to an embodiment.

FIG. 4 is a sectional view of a current confinement layer according to a first modification.

FIG. 5 is a sectional view of a current confinement layer according to a second modification.

FIG. 6 is a sectional view of a current confinement layer of a vertical cavity surface emitting laser according to another embodiment.

FIG. 7 is a sectional view of a current confinement layer of a vertical cavity surface emitting laser according to another embodiment.

FIG. 8 illustrates optical output distributions of laser light emitted from vertical cavity surface emitting lasers of a first experimental example, a second experimental example, and a third experimental example.

FIG. 9 is a graph representing the relationship between the bias current and the optical output of each mode of laser light in the vertical cavity surface emitting laser of the first experimental example.

FIG. 10 is a graph representing the relationship between the bias current and the optical output of each mode of laser light in the vertical cavity surface emitting laser of the second experimental example.

FIG. 11 is a graph representing the relationship between the bias current and the optical output of each mode of laser light in the vertical cavity surface emitting laser of the third experimental example.

### DESCRIPTION OF EMBODIMENTS

### Description of Embodiments of Present Disclosure

A vertical cavity surface emitting laser according to an embodiment includes a substrate having a main surface including a III-V group compound semiconductor and a semiconductor structure having a post disposed on the main surface. The main surface has an off-angle greater than 2° with respect to a (100) plane. The post includes an active layer and a current confinement layer that are arranged in a first direction intersecting the main surface. The current confinement layer includes an aperture portion and an insulation portion surrounding the aperture portion. The current confinement layer has a uniaxially symmetric shape or an asymmetric shape in a section perpendicular to the first direction.

In the vertical cavity surface emitting laser, the main surface of the substrate has a comparatively large off-angle. In this case, a lower-order mode is dominant in emitted laser light. Thus, laser light having a small near field pattern can be emitted. It is estimated that the reason why a lower-order mode is dominant is that a bias in current distribution in a section of the aperture portion of the current confinement layer is reduced.

Moreover, the section of the current confinement layer has a uniaxially symmetric shape or an asymmetric shape. In this case, compared with a case where the section of the current confinement layer has a shape that is symmetric with respect to two or more axes, the dominant mode is not likely to change even when the value of a current supplied to the active layer changes. As a result, it is possible to reduce change in the optical output distribution of laser light in accordance with change in the value of the current.

The off-angle may be 6° or greater.

The aperture portion may have an asymmetric shape in the section.

The aperture portion may include a III-V group compound semiconductor including aluminum as a III group element, and the insulation portion may include aluminum oxide. In this case, the insulation portion can be formed by oxidizing the III-V group compound semiconductor including aluminum.

The semiconductor structure may include a first distributed Bragg reflector and a second distributed Bragg reflector, and the active layer may be disposed between the first distributed Bragg reflector and the second distributed Bragg reflector in the first direction. In this case, a resonator is formed between the first distributed Bragg reflector and the second distributed Bragg reflector.

The vertical cavity surface emitting laser may be configured to emit laser light including a plurality of modes when a current is supplied to the active layer through the current confinement layer, the plurality of modes may include a 0th-order mode having a largest wavelength, a 1st-order mode having a second-largest wavelength, and a 2nd-order mode having a third-largest wavelength, and an optical output of the 2nd-order mode may be largest among optical outputs of the plurality of modes when a value of the current is in the range of 1.5 mA to 10 mA. In this case, even when the value of the current changes across the range, change in the optical output distribution of laser light is small.

### Details of Embodiments of Present Disclosure

Hereafter, embodiments of the present disclosure will be described in detail with reference to the drawings. In the description of the drawings, the same reference numerals will be used for the same or equivalent elements, and redundant descriptions will be omitted. In the drawings, XYZ coordinate axes are illustrated as necessary. The X-axis direction, the Y-axis direction, and the Z-axis direction intersect (for example, perpendicularly intersect) each other.

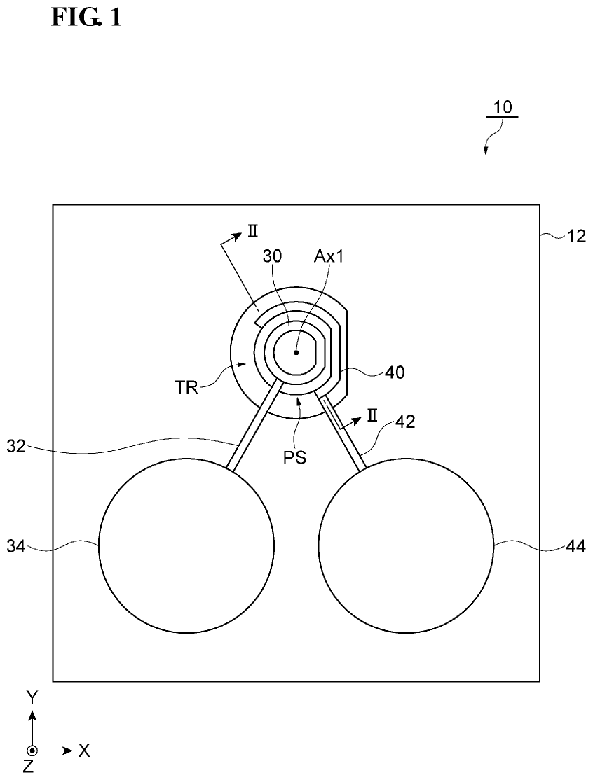

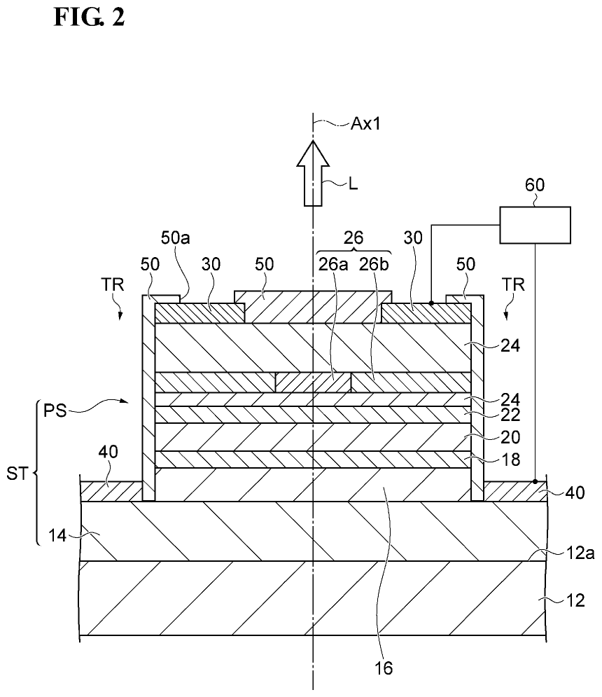

FIG. 1 is a schematic plan view of a vertical cavity surface emitting laser according to an embodiment. FIG. 2 is a sectional view taken along line II-II of FIG. 1. A vertical cavity surface emitting laser (VCSEL) 10 illustrated in FIGS. 1 and 2 includes a substrate 12 and a semiconductor structure ST.

The substrate 12 has a main surface 12a including a III-V group compound semiconductor. The substrate 12 may be a III-V group compound semiconductor substrate, or may include a III-V group compound semiconductor layer disposed on the main surface 12a and a base substrate supporting the III-V group compound semiconductor layer. The III-V group compound semiconductor includes, for example, GaAs.

The main surface 12a of the substrate 12 has an off-angle greater than 2° with respect to a (100) plane. The off-angle may be 6° or greater. The off-angle may be 25° or less. The direction of the normal vector of the main surface 12a (the positive direction of the Z-axis direction) is, for example, a direction that is inclined by the off-angle from the <100> direction, which is the direction of the normal vector of the (100) plane, toward the <1-1-1> direction. The positive direction of the X-axis direction is, for example, a direction that is inclined by the off-angle from the <01-1> direction. The positive direction of the Y-axis direction is, for example, a direction that is inclined by the off-angle from the <0-1-1> direction.

The semiconductor structure ST has a post PS disposed on the main surface 12a. For example, a trench TR is disposed around the post PS. The semiconductor structure ST may include a first lower distributed Bragg reflector 14 disposed between the main surface 12a and the post PS. The first lower distributed Bragg reflector 14 has a semiconductor stack structure of a first conductive type (for example, n-type). The semiconductor stack structure includes a first semiconductor layer and a second semiconductor layer that are alternately arranged in the Z-axis direction. The first semiconductor layer and the second semiconductor layer have refractive indices that differ from each other.

The post PS includes an active layer 20 and a current confinement layer 26 that are arranged in a first direction (the Z-axis direction) intersecting (for example, perpendicularly intersecting) the main surface 12a. The active layer 20 has, for example, a quantum well structure. The current confinement layer 26 includes an aperture portion 26a and an insulation portion 26b surrounding the aperture portion 26a. A first axis Ax1 extending in the Z-axis direction passes through the aperture portion 26a. The aperture portion 26a may include a III-V group compound semiconductor including aluminum as a III group element. The aperture portion 26a includes, for example, AlGaAs. The insulation portion 26b includes, for example, aluminum oxide. In this case, the insulation portion 26b can be formed by oxidizing the III-V group compound semiconductor including aluminum by using, for example, water or the like.

The post PS may include a second lower distributed Bragg reflector 16 disposed between the active layer 20 and the first lower distributed Bragg reflector 14. The second lower distributed Bragg reflector 16 has a semiconductor stack structure of the first conductive type (for example, n-type). The semiconductor stack structure includes a third semiconductor layer and a fourth semiconductor layer that are alternately arranged in the Z-axis direction. The third semiconductor layer and the fourth semiconductor layer have refractive indices that differ from each other. The first lower distributed Bragg reflector 14 and the second lower distributed Bragg reflector 16 are included in the first distributed Bragg reflector. The active layer 20 can be disposed between the current confinement layer 26 and the second lower distributed Bragg reflector 16. A spacer layer 18 may be disposed between the active layer 20 and the second lower distributed Bragg reflector 16. A spacer layer 22 may be disposed between the active layer 20 and the current confinement layer 26.

The post PS may include an upper distributed Bragg reflector 24 (a second distributed Bragg reflector). A resonator is formed between the upper distributed Bragg reflector 24 and the first and second lower distributed Bragg reflectors 14 and 16. The upper distributed Bragg reflector 24 has a semiconductor stack structure of a second conductive type (for example, p-type). The semiconductor stack structure includes a fifth semiconductor layer and a sixth semiconductor layer that are alternately arranged in the Z-axis direction. The fifth semiconductor layer and the sixth semiconductor layer have refractive indices that differ from each other. The upper distributed Bragg reflector 24 may include the current confinement layer 26. In this case, the current confinement layer 26 is disposed between an upper portion and a lower portion of the upper distributed Bragg reflector 24. The current confinement layer 26 may be disposed between the upper distributed Bragg reflector 24 and the active layer 20.

An insulation layer 50 may be disposed on an upper surface and a side surface of the post PS. The insulation layer 50 has an opening 50a in the upper surface of the post PS. A first electrode 30, which is electrically connected to the upper surface of the post PS, may be disposed in the opening 50a. The first electrode 30 has a ring shape surrounding the first axis Ax1. The first electrode 30 is connected to a pad electrode 34 via a wiring conductor 32. A second electrode 40, which is electrically connected to the first lower distributed Bragg reflector 14, may be disposed at the bottom of the trench TR. The second electrode 40 is connected to a pad electrode 44 via a wiring conductor 42. A bias power source 60 can be electrically connected to the first electrode 30 and the second electrode 40. To be specific, the bias power source 60 is connected to the pad electrode 34 and the pad electrode 44 via wiring. The bias power source 60 can apply a voltage between the first electrode 30 and the second electrode 40.

When a voltage is applied between the first electrode 30 and the second electrode 40, a bias current is supplied to the active layer 20 through the current confinement layer 26. Thus, laser light L including a plurality of modes (transverse modes) is emitted in the Z-axis direction. The vertical cavity surface emitting laser 10 is configured to emit the laser light L including the plurality of modes when the bias current is supplied to the active layer 20 through the current confinement layer 26. The laser light L is emitted along the first axis Ax1. The plurality of modes include the 0th-order mode, the 1st-order mode, the 2nd-order mode, . . . , and the nth-order mode. n is an integer that is, for example, 5 or greater. The 0th-order mode has the largest wavelength. When it is assumed that the wavelength decreases as the order increases, the 1st-order mode has the second-largest wavelength. The 2nd-order mode has the third-largest wavelength. The nth-order mode has the (n+1)th largest wavelength. In the vertical cavity surface emitting laser 10, the optical output of the 2nd-order mode may be the largest among the optical outputs of the plurality of modes when the value of the bias current is in the range of 1.5 mA to 10 mA or in the range of 4 mA to 8 mA.

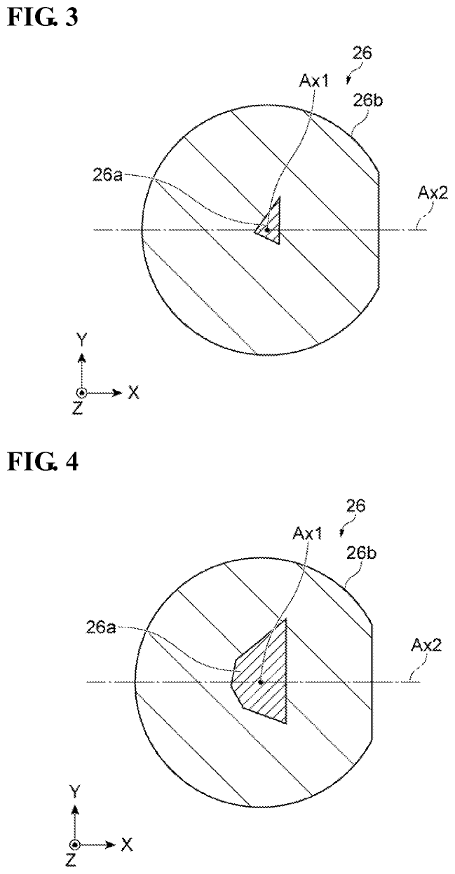

FIG. 3 is a sectional view of the current confinement layer 26. As illustrated in FIG. 3, the current confinement layer 26 has a uniaxially symmetric shape in a section (XY section) perpendicular to the Z-axis direction. A uniaxially symmetric shape is a shape that is symmetric with respect to a single axis. The current confinement layer 26 has a shape that is symmetric with respect to only a second axis Ax2 extending in the X-axis direction. The current confinement layer 26 has a shape that is asymmetric with respect to all axes other than the second axis Ax2 in the XY section. On the second axis Ax2, the distance from the first axis Ax1 to one edge is greater than the distance from the first axis Ax1 to the other edge. In the XY section, the current confinement layer 26 has, for example, a shape including an arc portion centered on the first axis Ax1 and a linear portion extending in the Y-axis direction. The center angle of the arc portion is, for example, greater than 180°. The length of the linear portion is, for example, less than the diameter of the arc portion and greater than the radius of the arc portion. The post PS has the same shape as the current confinement layer 26 in the XY section.

The aperture portion 26a has the same off-angle as the main surface 12a of the substrate 12 in the XY section. The aperture portion 26a has an asymmetric shape in the XY section. The aperture portion 26a has a shape that is asymmetric with respect to all axes in the XY section. The largest length of the aperture portion 26a in the Y-axis direction is greater than the largest length of the aperture portion 26a in the X-axis direction. The aperture portion 26a has, for example, the shape of a triangle having three sides that differ from each other in length. The longest side extends in the Y-axis direction. Each vertex of the triangle may be rounded.

FIG. 4 is a sectional view of a current confinement layer according to a first modification. In the present modification, the aperture portion 26a has an asymmetric shape in the XY section. The aperture portion 26a has, for example, the shape of a pentagon having five sides that differ from each other in length. The longest side extends in the Y-axis direction. The other four sides are located between two ends of the longest side in the Y-axis direction. Each vertex of the pentagon may be rounded.

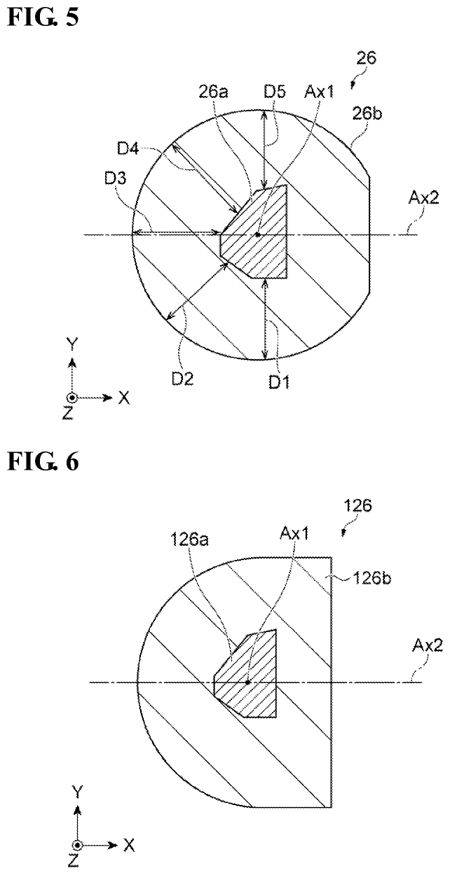

FIG. 5 is a sectional view of a current confinement layer according to a second modification. In the present modification, the aperture portion 26a has an asymmetric shape in the XY section. The aperture portion 26a has, for example, the shape of a hexagon having six sides that differ from each other in length. The longest side extends in the Y-axis direction. The other five sides are located between two ends of the longest side in the Y-axis direction. Each vertex of the hexagon may be rounded.

The shape and area of the aperture portion 26a are adjustable in accordance with, for example, the area of the current confinement layer 26 in the XY section, the oxidation time when forming the insulation portion 26b, the off-angle of the main surface 12a of the substrate 12, and the like. When the area of the current confinement layer 26 in the XY section is small, the shape of the aperture portion 26a is close to the shape of the triangle of FIG. 3. When the area of the current confinement layer 26 in the XY section is large, the shape of the aperture portion 26a is close to the shape of the pentagon of FIG. 4. When the area of the current confinement layer 26 in the XY section is larger, the shape of the aperture portion 26a is close to the shape of the hexagon of FIG. 5. The shape of the aperture portion 26a may be the shape of another polygon or may be a shape including a curve. The area of the aperture portion 26a decreases, for example, as the oxidization time when forming the insulation portion 26b is reduced. The area of the aperture portion 26a in the XY section is, for example, in the range of 7 μm² to 100 μm² or in the range of 12 μm² to 100 μm². When the area of the aperture portion 26a is less than 7 μm², laser oscillation in a single transverse mode (only the 0th-order mode) is maintained even when the bias current is increased, and a plurality of modes are not likely to be included in the laser light L. When the area of the aperture portion 26a is less than 12 μm², a plurality of modes are not likely to be included in the laser light L when the bias current is small.

In the XY section of FIG. 5, the current confinement layer 26 has first to fifth distances D1 to D5 between the edge of the current confinement layer 26 and the edge of the aperture portion 26a. The first to fifth distances D1 to D5 extend, in five directions each of which is sequentially rotated clockwise by 45° in the XY section. The first distance D1 and the fifth distance D5 extend in the Y-axis direction. The fifth distance D5 is located on a side opposite to the first distance D1 with respect to the second axis Ax2. The second distance D2 and the fourth distance D4 each extend in a direction that is inclined by 45° with respect to the Y-axis direction. The fourth distance D4 is located on a side opposite to the second distance D2 with respect to the second axis Ax2. The third distance D3 extends in the X-axis direction.

The number of bonds of a III group element (for example, aluminum) at the third distance D3 is one. On the other hand, the number of bonds of the III group element at each of the second distance D2 and the fourth distance D4 is two. Thus, the progress of an oxidation process at the third distance D3 is slower than the progress of the oxidation process at each of the second distance D2 and the fourth distance D4. Accordingly, the third distance D3 is less than the second distance D2 and the fourth distance D4.

The number of bonds of the III group element at each of the first distance D1 and the fifth distance D5 is one when the off-angle is 0°. At the first distance D1, the number of bonds of the III group element increases when the off-angle is increased because the step density increases. On the other hand, at the fifth distance D5, the number of bonds of the III group element does not increase even when the off-angle is increased. Thus, progress of the oxidation process at the fifth distance D5 is slower than the progress of oxidation process at the first distance D1. Accordingly, the fifth distance D5 is less than the first distance D1.

Because the oxidation process progresses three-dimensionally, the progress of oxidation process at the fourth distance D4, which is between the third distance D3 and the fifth distance D5, is slower than the progress of oxidation process at the second distance D2, which is between the third distance D3 and the first distance D1. Accordingly, the fourth distance D4 is less than the second distance D2.

In the vertical cavity surface emitting laser 10, the main surface 12a of the substrate 12 has a comparatively large off-angle. In this case, in emitted laser light L, a lower-order mode (for example, the 2nd-order mode) is dominant. A lower-order mode has large optical output at the center of a cross section of laser light L. A higher-order mode has large optical output at an outer portion of a cross section of laser light L. Thus, laser light L having a small near field pattern can be emitted. It is estimated that the reason why a lower-order mode is dominant is that deviation of current distribution in the XY section of the aperture portion 26a of the current confinement layer 26 is reduced.

The XY section of the current confinement layer 26 has a uniaxially symmetric shape. In this case, compared with a case where the XY section of the current confinement layer has a shape that is symmetric with respect to two or more axes (for example, a case where the XY section of the current confinement layer has a circular shape or a rectangular shape), the dominant mode is not likely to change even when the value of the bias current supplied to the active layer 20 changes. For example, the optical output of a lower-order mode (for example, 2nd-order mode) is the largest when the value of the bias current is in the range of 1.5 mA to 10 mA. As a result, it is possible to reduce change in the optical output distribution of laser light L in accordance with change in the value of the bias current.

When the off-angle of the main surface 12a is 6° or greater, a mode of a further lower order is dominant. Therefore, it is possible to further reduce change in the optical output distribution of laser light L in accordance with the change in the value of the bias current.

FIG. 6 is a sectional view of a current confinement layer of a vertical cavity surface emitting laser according to another embodiment. The vertical cavity surface emitting laser according to the present embodiment has the same configuration as the vertical cavity surface emitting laser 10, except that the vertical cavity surface emitting laser according to the present embodiment includes a current confinement layer 126 instead of the current confinement layer 26. The current confinement layer 126 has the same configuration as the current confinement layer 26, except that the shape thereof in the XY section differs from that of the current confinement layer 26. The current confinement layer 126 has a uniaxially symmetric shape in the XY section. The current confinement layer 126 has a shape including, for example, a semicircular portion centered on the first axis Ax1, a first linear portion extending in the Y-axis direction, a second linear portion connecting one end of the semicircular portion and one end of the first linear portion, and a third linear portion connecting the other end of the semicircular portion and the other end of the first linear portion.

The current confinement layer 126 includes an aperture portion 126a and an insulation portion 126b surrounding the aperture portion 126a. The first axis Ax1 extending in the Z-axis direction passes through the aperture portion 126a.

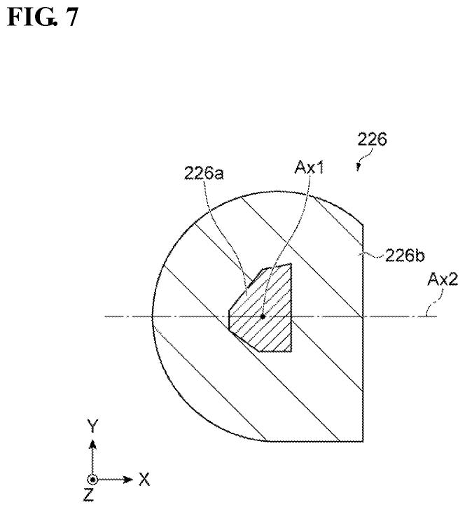

FIG. 7 is a sectional view of a current confinement layer of a vertical cavity surface emitting laser according to another embodiment. The vertical cavity surface emitting laser according to the present embodiment has the same configuration as the vertical cavity surface emitting laser 10, except that the vertical cavity surface emitting laser according to the present embodiment includes a current confinement layer 226 instead of the current confinement layer 26. The current confinement layer 226 has the same configuration as the current confinement layer 26, except that the shape thereof of the XY section differs from that of the current confinement layer 26. The current confinement layer 226 has an asymmetric shape in the XY section. The current confinement layer 226 has a shape that is asymmetric with respect to all axes in the XY section. The current confinement layer 226 has a shape including, for example, a semicircular portion centered on the first axis Ax 1, a first linear portion extending in the Y-axis direction, a second linear portion connecting one end of the semicircular portion and one end of the first linear portion, and an arc portion connecting the other end of the semicircular portion and the other end of the first linear portion and centered on the first axis Ax1.

The current confinement layer 226 includes an aperture portion 226a and an insulation portion 226b surrounding the aperture portion 226a. The first axis Ax1 extending in the Z-axis direction passes through the aperture portion 226a.

Also with the embodiments illustrated in FIGS. 6 and 7, advantageous effects similar to those of the vertical cavity surface emitting laser 10 can be obtained.

Heretofore, preferred embodiments of the present disclosure have been described in detail. However, the present disclosure is not limited to the embodiments described above. For example, the shape of the current confinement layer 26 in the XY section may be a polygon or a shape including a curve other than an arc. The shape of the aperture portion 26a in the XY section may be a shape including a curve other than an arc.

Hereafter, vertical cavity surface emitting lasers of a first experimental example, a second experimental example, and a third experimental example will be described. However, the present disclosure is not limited to the following examples.

### First Experimental Example

A vertical cavity surface emitting laser of the first experimental example, having the same structure as the vertical cavity surface emitting laser 10, was fabricated. A GaAs substrate was used as the substrate 12. The main surface 12a of the substrate 12 had an off-angle of 15° with respect to the (100) plane. By oxidizing an AlGaAs layer with water, the current confinement layer 26, having the aperture portion 26a including AlGaAs and the insulation portion 26b including aluminum oxide, was formed. The aperture portion 26a had a hexagonal shape of FIG. 5 in the XY section. The area of the aperture portion 26a in the XY section was 38 μm².

### Second Experimental Example

A vertical cavity surface emitting laser of the second experimental example was fabricated in the same way as the first experimental example, except that the off-angle of the main surface 12a of the substrate 12 was 2°.

### Third Experimental Example

A vertical cavity surface emitting laser of the third experimental example was fabricated in the same way as the first experimental example, except that the shape of each of the current confinement layer 26 and the aperture portion 26a was a circle.

### Evaluation

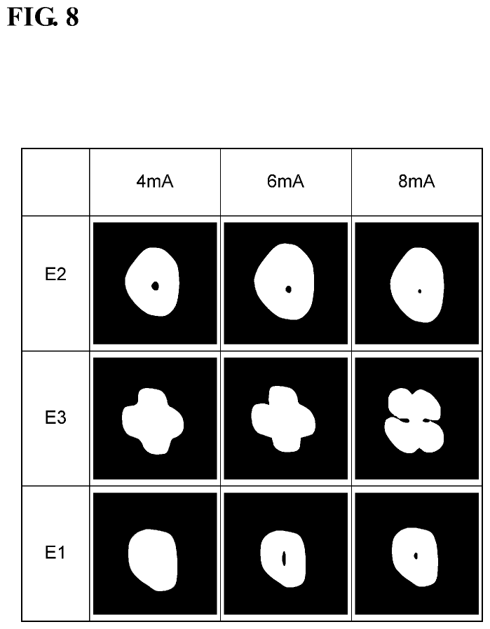

Regarding the vertical cavity surface emitting lasers of the first experimental example, the second experimental example, and the third experimental example, the bias current was changed to 4 mA, 6 mA, or 8 mA, and the optical output distribution of the laser light L as seen from the Z-axis direction was obtained. The optical output distribution was obtained by accumulating optical outputs of all modes included in the laser light L. The results are Illustrated in FIG. 8.

FIG. 8 illustrates the optical output distributions of laser light emitted from vertical cavity surface emitting lasers of the experimental example, the second experimental example, and the third experimental example. In FIG. 8, the column E1 represents the optical output distribution of the first experimental example. The column E2 represents the optical output distribution of the second experimental example. The column E3 represents the optical output distribution of the third experimental example. In each optical output distribution of FIG. 8, a white portion represents a portion where large optical output was obtained. As illustrated in FIG. 8, in the third experimental example, the optical output distribution of the laser light L considerably changed as the bias current changed. In the first experimental example and the second experimental example, even when the bias current changed, change in the optical output distribution of the laser light L was less than that of the third experimental example. Moreover, in the first experimental example, the spread of the optical output distribution was smaller than that of the second experimental example. Thus, with the first experimental example, a near field pattern smaller than that of the second experimental example was obtained.

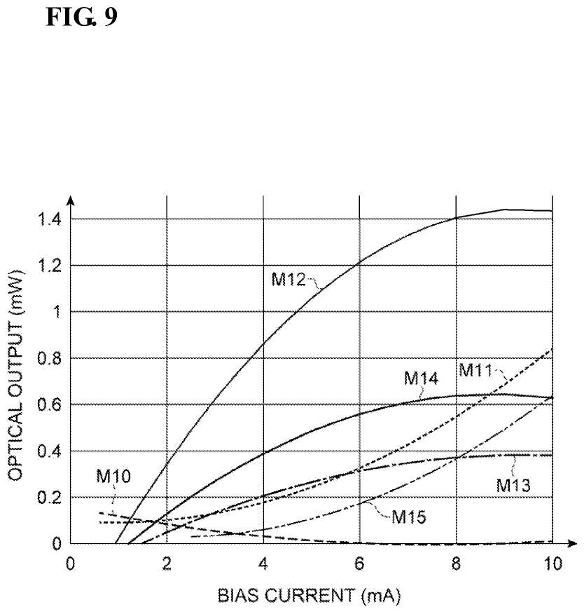

FIG. 9 is a graph representing the relationship between the bias current and the optical output of each mode of laser light of the vertical cavity surface emitting laser of the first experimental example. The horizontal axis represents the bias current (mA). The vertical axis represents the optical output (mW). As represented in FIG. 9, in the first experimental example, the optical output of the 2nd-order mode M12 was the largest when the value of the bias current was in the range of 1.5 mA to 10 mA. To be specific, the optical output of the 2nd-order mode M12 was greater than the optical output of each of the 0th-order mode M10, the 1st-order mode M11, the 3rd-order mode M13, the 4th-order mode M14, and the 5th-order mode M15. Thus, it can be seen that the 2nd-order mode M12 was dominant in the first experimental example.

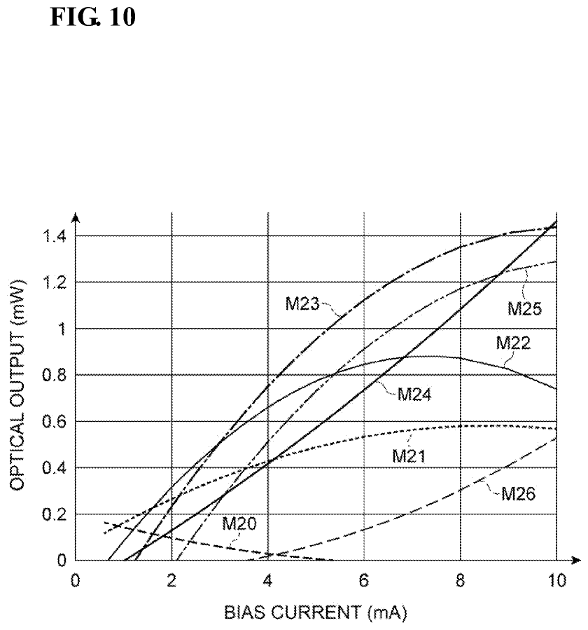

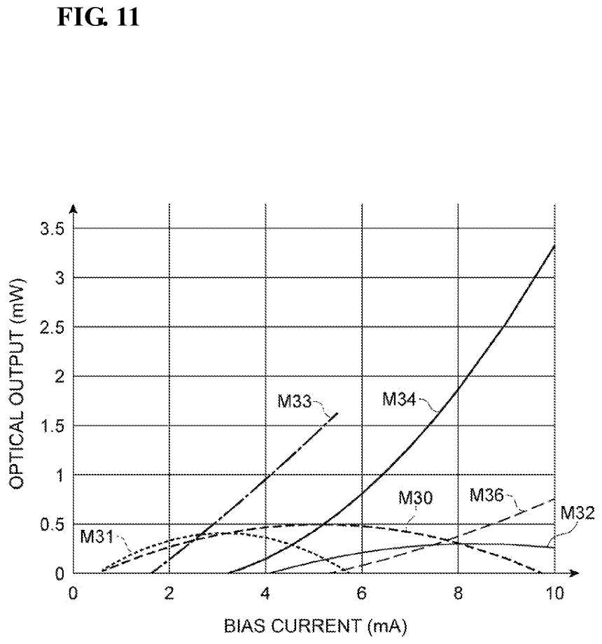

FIG. 10 is a graph representing the relationship between the bias current and the optical output of each mode of laser light of the vertical cavity surface emitting laser of the second experimental example. The horizontal axis represents the bias current (mA). The vertical axis represents the optical output (mW). As represented in FIG. 10, in the second experimental example, the optical output of each of the 3rd-order mode M23 and the 5th-order mode M25 was comparatively large. The optical output of each of the 0th-order mode M20, the 1st-order mode M21, the 2nd-order mode M22, the 4th-order mode M24, and the 6th-order mode M26 was comparatively small. Thus, it can be seen that the 3rd-order mode M23 and the 5th-order mode M25 were dominant in the second experimental example.

FIG. 11 is a graph representing the relationship between the bias current and the optical output of each mode of laser light of the vertical cavity surface emitting laser of the third experimental example. The horizontal axis represents the bias current (mA). The vertical axis represents the optical output (mW). As represented in FIG. 11, in the third experimental example, the optical output of each of the 3rd-order mode M33 or the 4th-order mode M34 was comparatively large. The optical output of each of the 0th-order mode M30, the 1st-order mode M31, the 2nd-order mode M32, and the 6th-order mode M36 was comparatively small. Thus, it can be seen that the 3rd-order mode M33 or the 4th-order mode M34 was dominant. Moreover, it can be seen that the dominant mode changed when the bias current was changed.

It should be understood that the embodiments disclosed herein are examples in all respects and are not limiting. The scope of the present disclosure is represented not by the above description but by the claims, and it is intended that the scope includes all modifications within the meaning of the equivalents of the claims.

What is claimed is:

1. A vertical cavity surface emitting laser comprising:
a substrate having a main surface including a III-V group compound semiconductor; and
a semiconductor structure having a post disposed on the main surface,
wherein the main surface has an off-angle greater than 2° with respect to a (100) plane,
wherein the post includes an active layer and a current confinement layer that are arranged in a first direction intersecting the main surface,
wherein the current confinement layer includes an aperture portion and an insulation portion surrounding the aperture portion, and
wherein the current confinement layer has a uniaxially symmetric shape or an asymmetric shape in a section perpendicular to the first direction.

2. The vertical cavity surface emitting laser according to claim 1, wherein the off-angle is 6° or greater.

3. The vertical cavity surface emitting laser according to claim 1, wherein the aperture portion has an asymmetric shape in the section.

4. The vertical cavity surface emitting laser according to claim 1, wherein the aperture portion includes a III-V group compound semiconductor including aluminum as a III group element, and the insulation portion includes aluminum oxide.

5. The vertical cavity surface emitting laser according to claim 1,
wherein the semiconductor structure includes a first distributed Bragg reflector and a second distributed Bragg reflector, and
wherein the active layer is disposed between the first distributed Bragg reflector and the second distributed Bragg reflector in the first direction.

6. The vertical cavity surface emitting laser according to claim 1,
wherein the vertical cavity surface emitting laser is configured to emit laser light including a plurality of modes when a current is supplied to the active layer through the current confinement layer,
wherein the plurality of modes include a 0th-order mode having a largest wavelength, a 1st-order mode having a second-largest wavelength, and a 2nd-order mode having a third-largest wavelength, and
wherein an optical output of the 2nd-order mode is largest among optical outputs of the plurality of modes when a value of the current is in a range of 1.5 mA to 10 mA.
